(19) United States
(12) Patent Application Publication
(10) Pub. No.: US 2011/0314667 A1
(43) Pub. Date: Dec. 29, 2011

(54) Method of manufacturing printed circuit board including electronic component embedded therein

(75) Inventors: Sang Jin Baek, Gyunggi-do (KR); Yul Kyo Chung, Gyunggi-do (KR); Hyung Mi Jung, Gyunggi-do (KR); Jung Soo Byun, Gyunggi-do (KR)

(73) Assignee: SAMSUNG ELECTRO-MECHANICS CO., LTD., Suwon (KR)

(21) Appl. No.: 13/137,655

(22) Filed: Aug. 31, 2011

Related U.S. Application Data
(62) Division of application No. 12/222,799, filed on Aug. 15, 2008.

(30) Foreign Application Priority Data
Jun. 16, 2008 (KR) 10-2008-0056487

(51) Int. Cl. H05K 3/30

(52) U.S. Cl. 29/832

(57) ABSTRACT

A method of manufacturing a printed circuit board including an electronic component embedded therein, including: preparing a core substrate, which has a cavity formed therein and which includes internal circuit layers formed thereon; attaching a tape to one side of the core substrate; attaching an electronic component on the tape such that the cavity receives the electronic component therein; forming a first insulating layer on another side of the core substrate such that the first insulating layer infiltrates into the cavity; removing the tape attached to the one side of the core substrate, and forming connecting parts for electrically connecting electrode terminals of the electronic component to the internal circuit layer formed on the one side of the core substrate; and forming a second insulating layer on the one side of the core substrate from which the tape is removed

### CROSS-REFERENCE TO RELATED APPLICATIONS

This application is a U.S. divisional application of U.S. patent application Ser. No. 12/222,799, filed on Aug. 15, 2008, which claims earlier priority benefit to Korean Patent Application No. 10-2008-0056487 filed with the Korean Intellectual Property Office on Jun. 16, 2008, the disclosures of which are incorporated herein by reference.

### BACKGROUND

1. Field

The present invention relates generally to a printed circuit board including an electronic component embedded therein and a method of manufacturing the same, and, more particularly, to a printed circuit board including an electronic component embedded therein and a method of manufacturing the same, which electrically connects electrode terminals of an electronic component to an internal circuit layer, thus dispersing circuit density.

2. Description of the Related Art

These days, in response to the miniaturization and the increase in the functionality of electronic products, printed circuit boards, which include electronic components embedded therein, are getting a lot of attention.

In order to realize a printed circuit board including electronic components embedded therein, there exists a wide variety of surface-mounting technologies for mounting semiconductor devices such as Integrated Circuit (IC) chips on a printed circuit board. The surface-mounting technologies may include a wire bonding technology and a flip chip technology.

Among these, a surface-mounting process using the wire bonding technology is configured in a manner such that an electronic component, on which a designed circuit is printed, is bonded on a printed circuit board using adhesive, terminals (i.e., pads) of the electronic component are connected to lead frames of the printed circuit board via metal wires for the transmission of information therebetween, and the electronic component and the wires are subjected to a molding process using thermosetting resin or thermoplastic resin. for the transmission of information therebetween, and the electronic component and the wires are subjected to a molding process using thermosetting resin or thermoplastic resin.

Meanwhile, a surface-mounting process using the flip chip technology is configured in a manner such that external connecting terminals (i.e., bumps) having a size ranging from several μm to hundreds of μm are formed on an electronic component using connecting materials such as gold, solder and other metals, the electronic component including the bump formed thereon is flipped over so that the surface of the component faces a printed circuit board, and the electronic component is mounted on the printed circuit board in the flipped orientation, unlike the process using the wire bonding technology.

Since these surface-mounting processes are conducted in a common manner in which electronic component is mounted on the surface of a printed circuit board, the total thickness of the resulting product after the mounting process cannot be less than the sum of thicknesses of the printed circuit board and the electronic component, thus making the manufacture of a high-density product difficult. In addition, since electrical connection between the electronic component and the printed circuit board is achieved using the connecting terminals (pads or bumps), the electrical connection may be damaged or may malfunction due to breakage or corrosion of the connecting terminals, thus deteriorating the reliability of the product.

For this reason, in order to overcome the above problems, electronic components are embedded inside rather than outside the printed circuit, and a build-up layer is formed for the electrical connection, thereby realizing compact and high-density products, minimizing a wiring distance at a high frequency (100 MHz or higher), and avoiding the deterioration in reliability occurring at a stage of connecting components to each other in the surface-mounting process using the wire bonding technology or the flip chip technology.

FIGS. 1 to 7 are cross-sectional views showing a conventional process of manufacturing a printed circuit board including an electronic component embedded therein.

Referring to the drawings, the conventional process is now described.

First, as shown in FIG. 1, a core substrate 10, which is comprised of a copper clad laminate and an internal circuit layer 11 formed on the copper clad laminate, in which a cavity 12 for receiving an electronic component therein is formed in the copper clad laminate, is prepared.

As shown in FIG. 2, tape 13, which serves to support an electronic component, is attached to one side of the core substrate 10.

As shown in FIG. 3, an electronic component 14 having electrode terminals 15 thereon is inserted in the cavity 12, and is then attached to the tape 13 in a face-up orientation.

As shown in FIG. 4, thereafter, a first insulating layer 16 is formed on the other side of the core substrate 10 on which the tape 13 is not attached, and is also formed in a gap between the electronic component 14 and the inner wall of the cavity 12.

As shown in FIG. 5, the tape 13 is removed from the one side of the core substrate 10.

As shown in FIG. 6, a second insulating layer 17 is formed on the other side of the core substrate 10 from which the tape 13 is removed.

As shown in FIG. 7, finally, an external circuit layer 18, which has vias 19 connected to the internal circuit layer 11 or the electrode terminals 15 of the electronic component 14, is formed on the first insulating layer 16 and the second insulating layer 17.

However, in the conventional printed circuit board including an electronic component embedded therein, which is manufactured through the above-described process, the terminals 15 of the electronic component 14 are connected only to the external circuit layer 18 through the vias 19, and are not connected to the internal circuit layer 11. In other words, circuits are concentrated on the external circuit layer 18, and in the case in which the electronic component 14 has a great number of electrode terminals 15, the external layer 18 alone is not enough to accommodate to the great number of electrode terminals 15. Accordingly, there may be a disadvantageous limit to the number of electronic components 14 that can be embedded in the printed circuit board.

FIG. 8 shows a connection configuration between electrode terminals of an electronic component and the internal circuit layers, according to a conventional process. From the drawing, it will be appreciated that the electrode terminals 15 of the electronic component 14 and the internal circuit layer 11 are not electrically connected to each other. That is, it will be appreciated that none of the electrode terminals 15 of the electronic component 14 is connected to the internal circuit layer 11.

### SUMMARY

Accordingly, the present invention has been made keeping in mind the above problems occurring in the prior art, and the present invention provides a printed circuit board including an electronic component embedded therein and a method of manufacturing the printed circuit board, which electrically connects electrode terminals of an electronic component to an internal circuit layer, thus dispersing circuit density.

In one aspect, the present invention provides a printed circuit board including an electronic component embedded therein, including: a core substrate, which has a cavity formed therein and which includes internal circuit layers formed on both sides thereof; an electronic component received in the cavity; connecting parts for electrically connecting electrode terminals of the electronic component to the internal circuit layers; and insulating layers formed on both sides of the core substrate to cover the electronic component.

The printed circuit board may further including external circuit layers formed on the insulating layers.

The external circuit layers may be connected to the electrode terminals or the internal circuit layers through vias.

The connecting parts may connect the electrode terminals to the internal circuit layers in a horizontal orientation.

In another aspect, the present invention provides a method of manufacturing a printed circuit board including an electronic component embedded therein, including: preparing a core substrate, which has a cavity formed therein and which includes internal circuit layers formed thereon; attaching a tape to one side of the core substrate; attaching an electronic component on the tape such that the cavity receives the electronic component therein; forming a first insulating layer on another side of the core substrate such that the first insulating layer infiltrates into the cavity; removing the tape attached to the one side of the core substrate, and forming connecting parts for electrically connecting electrode terminals of the electronic component to the internal circuit layer formed on the one side of the core substrate; and forming a second insulating layer on the one side of the core substrate from which the tape is removed.

The tape may include a silicon rubber plate or a polyimide adhesive tape.

In the attaching the electronic component on the tape, the electronic component may be mounted in a face-down orientation such that the electrode terminals of the electronic component are attached to the tape.

In the removing the tape and forming the connecting parts, the connecting parts may be formed using an inkjet printing process or a screen printing process.

The connecting parts may be formed so as to connect the electrode terminals to the internal circuit layers in a horizontal orientation.

The method may further include, after the forming the second insulating layer, forming external circuit layers including vias on the first and second insulating layers.

In the forming the external circuit layers, the vias may be formed to connect the external circuit layers to the internal circuit layers or the electrode terminals.

The vias may be formed using any one of a mechanical drill, a CO₂ laser drill, a Nd-Yag laser drill and wet etching.

### BRIEF DESCRIPTION OF THE DRAWINGS

The above and other objects, features and other advantages of the present invention will be more clearly understood from the following detailed description taken in conjunction with the accompanying drawings, in which:

FIGS. 1 to 7 are cross-sectional views showing a conventional process of manufacturing a printed circuit board, including an electronic component embedded therein;

FIG. 8 is a view showing a connection configuration between an electronic component and internal circuit layers, according to a conventional process;

FIG. 9 is a cross-sectional view of a printed circuit board including an electronic component embedded therein, according to an embodiment of the present invention;

FIGS. 10 to 17 are cross-sectional views of a process of manufacturing a printed circuit board including an electronic component embedded therein, according to an embodiment of the present invention; and

FIG. 18 is a view showing a connection configuration between an electronic component and internal circuit layers, according to an embodiment of the present invention.

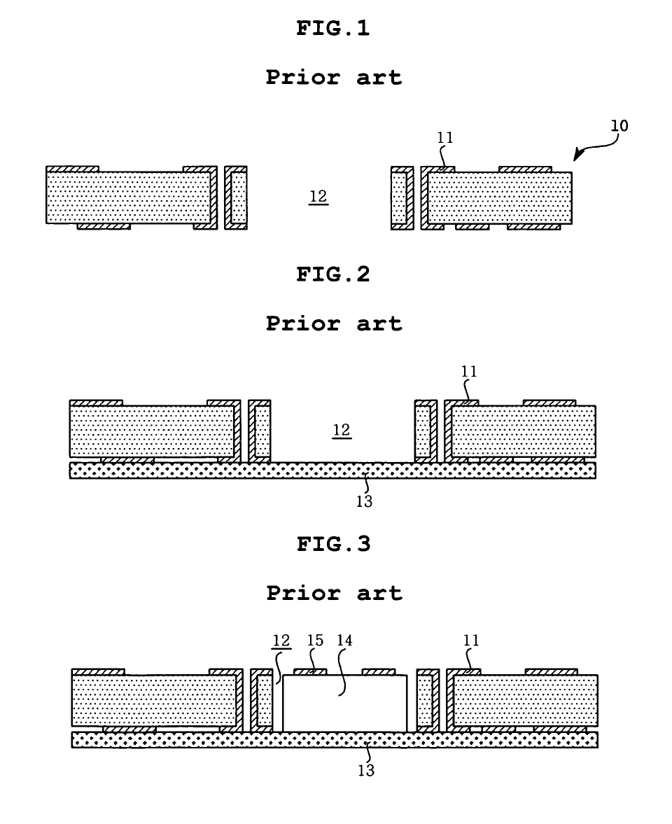

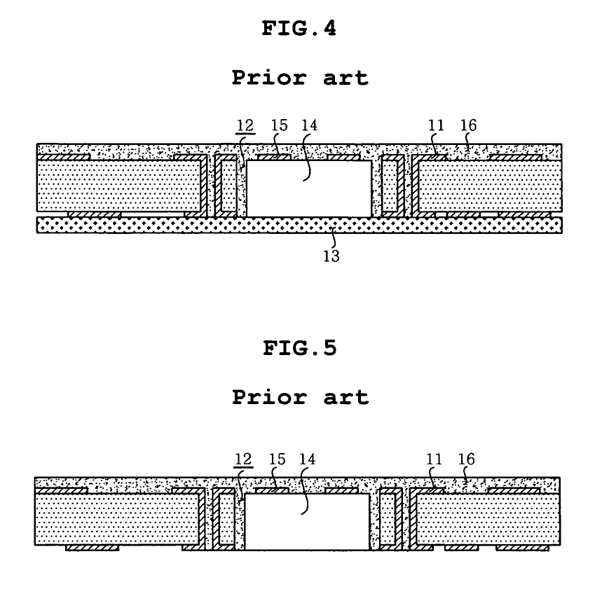

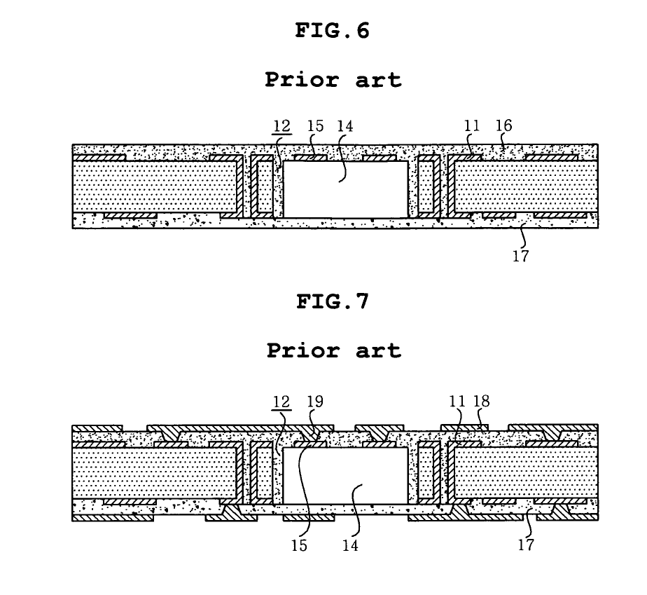

### DESCRIPTION OF EMBODIMENTS

Various objects, advantages and features of the invention will become apparent from the following description of embodiments with reference to the accompanying drawings. In the designation of reference numerals, it should be noted that the same reference numerals are used throughout the different drawings to designate the same or similar components. Also, in the description of the present invention, when it is considered that the detailed description of a related prior art may obscure the gist of the present invention, such detailed description is omitted.

Hereinafter, an embodiment of the present invention will be described in greater detail with reference to the following drawings.

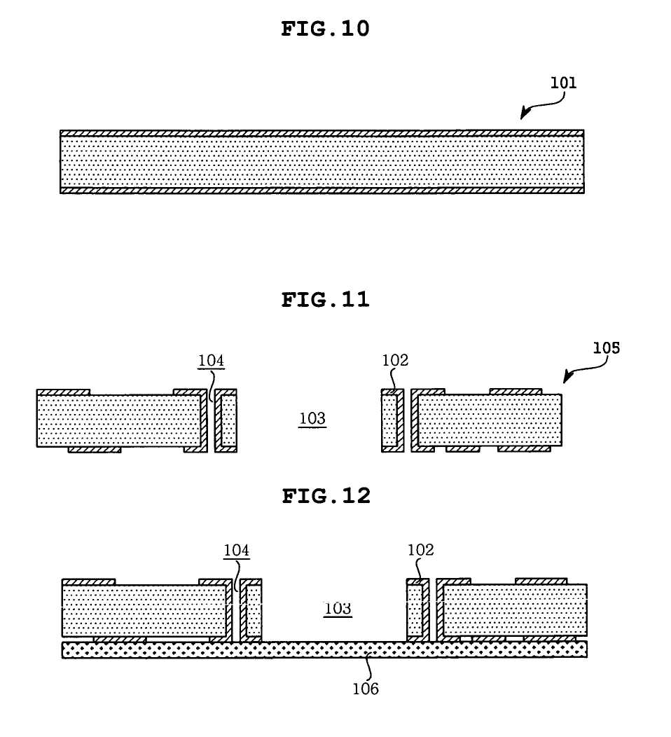

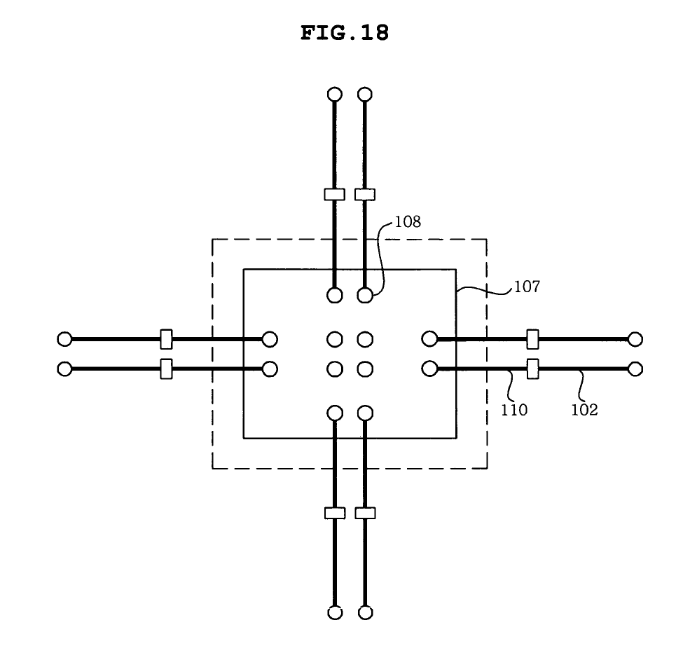

FIG. 9 is a cross-sectional view of a printed circuit board including an electronic component embedded therein, according to an embodiment of the present invention, FIGS. 10 to 17 are cross-sectional views sequentially showing a process of manufacturing the printed circuit board including an electronic component embedded therein, according to an embodiment of the present invention, and FIG. 18 is a view showing the connection configuration between electrode terminals of an electronic component and the internal circuit layer, according to a conventional process.

Referring to FIG. 9, the printed circuit board 100 including an electronic component embedded therein according to an embodiment of the present invention comprises a core substrate 105, an electronic component 107, connecting parts 110 and insulating layers 109, 111.

The core substrate 105 includes a cavity 103 for allowing the electronic component 107 to be mounted therein, internal circuit layers 102 formed on both sides of thereof and each including a circuit pattern and lands, and through-holes 104 for interlayer connection between the internal circuit layers 102.

The electronic component, which may be a semiconductor device, includes electrode terminals 108 connected to the circuit layers.

The connecting parts 110 are intended to be used for connections between the internal circuit layers 102 and some of the electrode terminals 108 of the electronic component 107, and may be provided in a plural number within a desired range.

The connecting parts 110 are formed such that the internal circuit layers 102 are horizontally connected to the electrode terminals 108 of the electrode component 107 therethrough.

The insulating layers 109, 111 are formed on both sides of the core substrate 105 to support the electronic component 107.

The insulating layers 109, 111 are provided thereon with external circuit layers 113, and are also provided therein with vias 112 for connecting the internal circuit layers 102 or the electrode terminals 108 to the external circuit layers 113.

FIGS. 10 to 17 are cross-sectional views sequentially showing a process of manufacturing the printed circuit board including an electronic component embedded therein, according to an embodiment of the present invention. Hereinafter, the process of manufacturing the printed circuit board is described with reference to the drawings.

As shown in FIG. 10, a double-sided copper clad laminate 101, which comprises a resin layer constituting a core substrate, and copper layers formed on both sides of the resin layer, is first prepared.

As shown in FIG. 11, internal circuit layers 102 and a cavity 103 are formed on and in the double-sided copper clad laminate 101, thus preparing a core substrate 105.

Thereafter, through-holes 104 are formed in the core substrate 105 for the connection between the internal circuit layers 102 formed on both sides of the double-sided copper clad laminate. These through-holes 104 are perforated using a mechanical drill or a laser drill (a CO₂ laser drill or a Nd-Yag laser drill).

The internal circuit layers 102 may be formed using a subtractive process, an additive process, or a modified semi-additive process (MSAP), depending on the manufacturing process. In this embodiment, although the internal circuit layers 102 are described as being formed using the subtractive process for the convenience of explanation, the manufacturing process according to the present invention should not be construed to be restricted to the subtractive process.

More specifically, the internal circuit layers 107 are formed in a manner such that a photosensitive photoresist is applied on a copper layer, a photomask is brought into close contact with the photoresist, the photoresist is patterned through light exposure using ultraviolet rays and development, and an unnecessary region of the copper layer is chemically etched by employing the patterned photoresist as an etching resist.

In this regard, the cavity 103, which is intended to accommodate an electronic component, may be formed concurrently with the drilling operation of forming the through-holes 104, or may be separately formed using a mechanical drill, a CO₂ laser drill or a Nd-Yag laser drill after the formation of the internal circuit layer 102.

Subsequently, as shown in FIG. 12, a tape 106, which is adapted to support an electronic component, is attached to one side of the core substrate 105.

At this point, as the tape 106, a silicone rubber plate or polyimide (PI) adhesive tape may be used. Accordingly, by employing the silicone rubber plate or the polyimide adhesive tape having adhesive force, the electronic component can be positioned at a desired location. Furthermore, the adhesive tape 106 may have thermal resistance so as not to be deformed even by heating or pressing in a subsequent process of printing and curing filler or forming an insulating layer for protecting the electrode component after the electronic component is mounted on the printed circuit board.

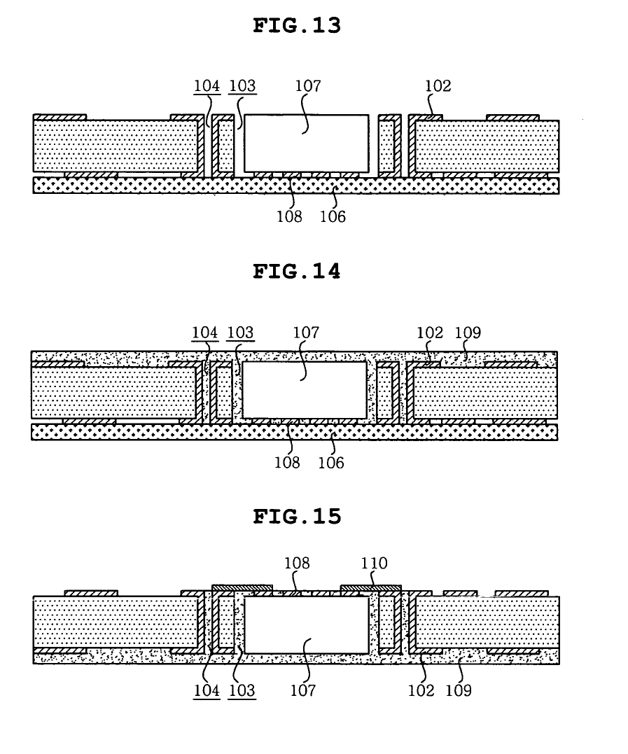

As shown in FIG. 13, the electrode component 107 is attached to the tape 106 adhered to one side of the core substrate 105 such that the electrode component 107 is received in the cavity 103.

At this time, the electronic component 107 is attached at a predetermined location, and is mounted in a face-down orientation such that the electrode terminals 108 of the electronic component 107 for the electrical connection with the circuit layer are attached to the tape 106.

Referring to FIG. 13, although the electronic component 107 is shown as being mounted in a face-down orientation, it is also possible to mount the electronic component in a face-up orientation, which should be understood to fall within the scope of the present invention.

As shown in FIG. 14, a first insulating layer 109 is formed on the other side of the core substrate 105, on which the tape is not attached, such that the through-holes 104 and the gap between the electronic component and the inner wall of the cavity 103 are filled with the first insulating layer 109.

Referring to FIG. 14, the formation of the first insulating layer 109 is conducted. However, prior to the formation of the first insulating layer, an encapsulation process may be first conducted in order to hold the electronic component 107 attached on the tape 106. The encapsulation process is conducted in a manner such that filler (not shown) is charged, i.e., impressed into in the gap between the inner wall of the cavity 103 and the electronic component 107 so as to hold the electronic component 107 at a predetermined location without displacement. The filling may be conducted using screen printing, mask printing, dispensing and the like, and the filler may be thermosetting resin, thermoplastic resin or combination thereof.

Subsequently, as shown in FIG. 15, after the core substrate 105 including the first insulating layer 109 formed thereon is turned over, the tape 106 is removed, and then connecting parts 110 are formed to electrically connect the circuit layers 102 with some of the electrode terminals of the electronic component 107.

At this time, the connecting parts 110 may be formed using an inkjet printing process or a screen printing process.

The inkjet printing process is conducted in a manner such that inkjet headers are positioned over the internal circuit layers 102 and the electrode terminals 108 of the electronic component 107, and ink is sprayed from the inkjet headers to form the connecting parts 110 for the electrical connection between the internal circuit layers 102 and the electrode terminals 108 of the electronic component 107. The ink is composed of metal (for example, silver) and solvent, and thus has electrical conductivity.

Meanwhile, the screen printing process is conducted in a manner such that conductive paste, which is used to constitute the connecting parts, is placed on a screen printing mask which has openings at desired locations, and the conductive paste is pressed and squeezed into the openings using a squeeze which moves from one side edge to the other side edge of the screen printing mask in a state of being in contact with the screen printing mask. During this operation, the openings in the mask are filled with the conductive paste so that the connecting parts 110 are formed on the internal circuit layers 102 and the electrode terminals 108 of the electrode component 107 over which the openings are positioned. Thereafter, the screen printing mask is removed.

Since the internal circuit layers 102 and the electrode terminals 108 of the electronic component 107 are electrically connected to each other using such a process, it is possible to solve the conventional problems in which the circuit density of external circuit layers is increased due to the connection between the external circuit layers and an electronic component through vias and it is impossible to respond to high density terminals of an electronic component. That is, since the electrode terminals 108 of the electronic component 107 are electrically connected to the internal circuit layers 102, the circuit density is dispersed.

Although the connecting parts 110 are shown as being formed on the internal circuit layers 102 and the electrode terminals 108, any structures for connecting the internal circuit layers 102 to the electrode terminals 108, such as a structure in which the internal circuit layers 102 and the electrode terminals 108 are connected to each other without the first insulating layer 109 disposed therebetween, should be understood to falling within the scope of the present invention.

The connecting parts 110 are formed so as to connect the internal circuit layers 102 to the electrode terminals 108 in a horizontal orientation. Referring to FIG. 15, the connecting parts 110 are shown as being disposed on the internal circuit layers 102 and the electrode terminals 108 to horizontally connect both the internal circuit layers 102 and the electrode terminals 108 to each other.

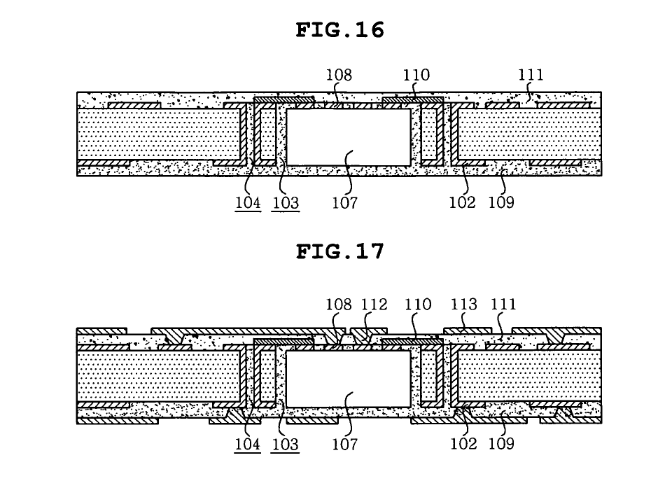

Thereafter, as shown in FIG. 16, a second insulating layer 111 is formed on the core substrate 105 on which the connecting parts 110 are formed. In this regard, since the second insulating layer 111 is formed in the same manner as the first insulating layer 109, a detailed description thereof is omitted.

By the above-described process, the printed circuit board 100 including an electronic component embedded therein is manufactured.

Furthermore, according to the process of manufacturing a printed circuit board including an electronic component embedded therein, as shown in FIG. 17, external circuit layers 113 including vias 112 are formed on the first insulating layer 109 and the second insulating layer 111.

At this point, the vias 112 are formed in a manner such that the vias 112 are connected to the electrode terminals 108, which are not connected to the internal circuit layers 102 or are adapted to connect the internal circuit layers 102 to the external circuit layers 113. The vias 112 are formed using any one of a mechanical drill, a laser drill (CO₂ laser drill or Nd-Yag laser drill) and wet etching.

Although not shown in the drawings, it will be apparent that a multilayered printed circuit board can be manufactured by further providing vias or bumps on both sides of the core substrate 105, including the electronic component 107 embedded therein.

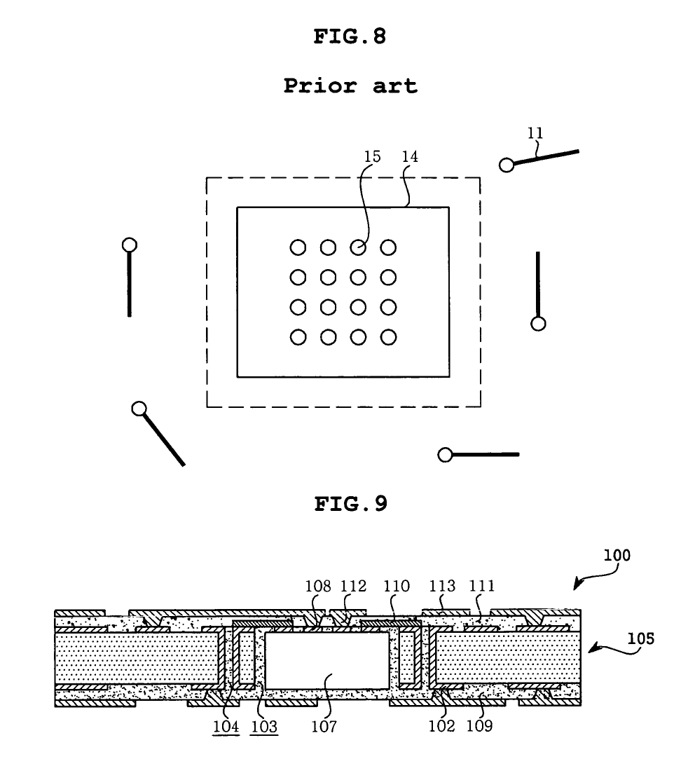

FIG. 18 shows the electrical connection configuration between the internal circuit layers 102 and the electrode terminals 108 of the electronic component 107, according to an embodiment of the present invention. As shown again in FIG. 8, in the conventional printed circuit board, the internal circuit layers 102 are not connected to any of the electrode terminals 108 of the electronic component 102, but simply serve as a ground. Contrary to this, it will be appreciated that the printed circuit board according to an embodiment of the present invention is configured such that the internal circuit layers 102 are electrically connected to the electrode terminals 108 of the electronic component 107, thus dispersing a circuit density. Specifically, it will be appreciated that eight electrode terminals 108 of 12 electrode terminals 108 formed on the electronic component 107 are the internal circuit layers 102 through the connecting parts 110. Although not shown in the drawing, the remaining electrode terminals 108 will be connected to the external circuit layers 113 through the vias 112.

As described above, according to the present invention, since some electrode terminals of an electronic component are first connected to internal circuit layers through connecting parts and the remaining electrode terminals are secondly connected to external circuit layers through vias, the circuit density is dispersed, with the result that, even when a large number of electrode terminals is required, the printed circuit board according to the present invention is capable of accommodating the electrode terminals.

Furthermore, since the present invention is adapted to electrically connect the electrode terminals of an electronic component to internal circuit layers, circuit density is dispersed, thus reducing the size of the overall printed circuit board.

Although the preferred embodiment of the present invention has been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A method of manufacturing a printed circuit board including an electronic component embedded therein, comprising:
preparing a core substrate, which has a cavity formed therein and which includes internal circuit layers formed thereon;
attaching a tape to one side of the core substrate;
attaching an electronic component on the tape such that the cavity receives the electronic component therein;
forming a first insulating layer on another side of the core substrate such that the first insulating layer infiltrates into the cavity;
removing the tape attached to the one side of the core substrate, and forming connecting parts for electrically connecting electrode terminals of the electronic component to the internal circuit layer formed on the one side of the core substrate; and
forming a second insulating layer on the one side of the core substrate from which the tape is removed.

2. The method according to claim 1, wherein the tape includes a silicon rubber plate or a polyimide adhesive tape.

3. The method according to claim 1, wherein, in the attaching the electronic component on the tape, the electronic component is mounted in a face-down orientation such that the electrode terminals of the electronic component are attached to the tape.

4. The method according to claim 1, wherein, in the removing the tape and forming the connecting parts, the connecting parts are formed using an inkjet printing process or a screen printing process.

5. The method according to claim 1, wherein the connecting parts are formed so as to connect the electrode terminals to the internal circuit layers in a horizontal orientation.

6. The method according to claim 1, further comprising, after the forming the second insulating layer, forming external circuit layers including vias on the first and second insulating layers.

7. The method according to claim 6, wherein, in the forming the external circuit layers, the vias are formed to connect the external circuit layers to the internal circuit layers or the electrode terminals.

8. The method according to claim 6, wherein the vias are formed using any one of a mechanical drill, a CO₂ laser drill, a Nd-Yag laser drill and wet etching.
